(19) United States
(12) Patent Application Publication
(10) Pub. No.: US 2021/0040616 A1
(43) Pub. Date: Feb. 11, 2021

(54) SHOWER HEAD AND SUBSTRATE TREATING APPARATUS HAVING THE SAME

(71) Applicant: SAMSUNG ELECTRONICS CO., LTD., Suwon-si (KR)

(72) Inventors: Junghwan PARK, Seoul (KR); Younghyun KIM, Seoul (KR); Sechung OH, Yongin-si (KR); Jungmin LEE, Gwangmyeong-si (KR); Kyungil HONG, Suwon-si (KR)

(21) Appl. No.: 16/891,177

(22) Filed: Jun. 3, 2020

(30) Foreign Application Priority Data
Aug. 6, 2019 (KR) 10-2019-0095434

(51) Int. Cl. C23C 16/455; B05B 1/18; C23C 16/458; C23C 16/06; H01L 27/22; H01L 43/02; H01L 43/12

(52) U.S. Cl. CPC C23C 16/45565; B05B 1/185; C23C 16/4583; H01L 43/12; H01L 27/222; H01L 43/02; C23C 16/06

(57) ABSTRACT

A shower head for a substrate treating apparatus and a substrate treating apparatus including the shower head, the shower head including a central head at a central portion of the shower head, the central head having a plurality of central holes through which a first injection gas is injectable; and a peripheral head at a peripheral portion of the shower head to enclose the central head, the peripheral head having a plurality of peripheral holes through which a second injection gas is injectable, wherein a total hole area of the peripheral holes is smaller than a total hole area of the central holes.

### CROSS-REFERENCE TO RELATED APPLICATION

Korean Patent Application No. 10-2019-0095434, filed on Aug. 6, 2019, in the Korean Intellectual Property Office, and entitled: “Shower Head and Substrate Treating Apparatus Having the Same,” is incorporated by reference herein in its entirety.

### BACKGROUND

### 1. Field

Embodiments relate to a shower head and a substrate treating apparatus having the same.

### 2. Description of the Related Art

A deposition apparatus may include a process chamber, a substrate holder at a lower portion of the process chamber, and a shower head at an upper portion of the process chamber. A substrate may be secured onto the substrate holder and source gases for forming a deposition layer on the substrate may be supplied into the process chamber though the shower head.

The source gases may be supplied into the shower head from a source tank under a single pressure and flux, so that substantially the same flux of the source gases may be injected into the process chamber on the peripheral portion and the central portion of the substrate.

### SUMMARY

The embodiments may be realized by providing a shower head for a substrate treating apparatus, the shower head including a central head at a central portion of the shower head, the central head having a plurality of central holes through which a first injection gas is injectable; and a peripheral head at a peripheral portion of the shower head to enclose the central head, the peripheral head having a plurality of peripheral holes through which a second injection gas is injectable, wherein a total hole area of the peripheral holes is smaller than a total hole area of the central holes.

The embodiments may be realized by providing a shower head for a substrate treating apparatus, the shower head including a central head at a central portion of the shower head, the central head having a plurality of central holes through which a first injection gas is injectable; a peripheral head at a peripheral portion of the shower head to enclose the central head, the peripheral head having a plurality of peripheral holes through which a second injection gas is injectable; and a flow cover detachably coupled to the peripheral head to control a flow of the second injection gas.

The embodiments may be realized by providing a substrate treating apparatus including a process chamber in which a substrate treating process to a substrate is conductable to form a deposition layer on the substrate; a substrate holder at a lower portion of the process chamber and on which the substrate is securable; a shower head at an upper portion of the process chamber, the shower head including a central head from which a first injection gas is injectable over a central portion of the substrate and peripheral head from which a second injection gas is injectable over a peripheral portion of the substrate such that a flux of the second injection gas is smaller than that of the first injection gas; a gas supplier to supply the first injection gas and the second injection gas to the shower head, the gas supplier including a first source line connected to the central head and a second source line connected to the peripheral head; and a flow controller to control the shower head and the gas supplier such that a flux of the second injection gas is controllable to thereby uniformize a thickness of the deposition layer across the central portion and the peripheral portion of the substrate.

### BRIEF DESCRIPTION OF THE DRAWINGS

Features will be apparent to those of skill in the art by describing in detail exemplary embodiments with reference to the attached drawings in which:

FIG. 1 is a perspective view illustrating a shower head for a substrate treating apparatus in accordance with an example embodiment;

FIG. 2A is a cross-sectional view of the shower head cut along a line I-I′ of FIG. 1;

FIG. 2B is a rear view of the shower head shown in FIG. 1;

FIG. 3 is a perspective view illustrating a shower head for a substrate treating apparatus in accordance with another example embodiment;

FIG. 4A is a cross-sectional view of the shower head cut along a line II-II′ of FIG. 3;

FIG. 4B is a rear view of the shower head shown in FIG. 3; and

FIG. 5 is a structural view illustrating a substrate treating apparatus including a shower head shown in FIGS. 1 to 2B.

### DETAILED DESCRIPTION

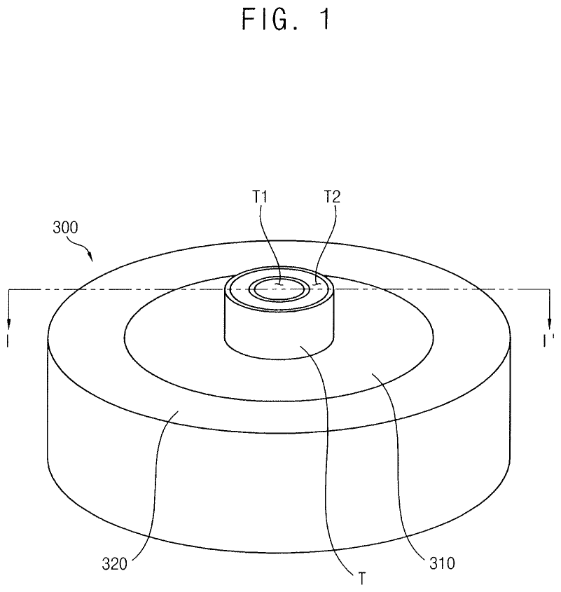

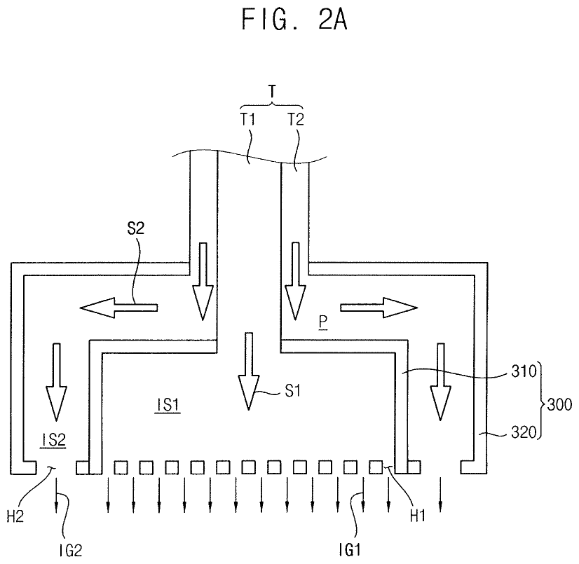

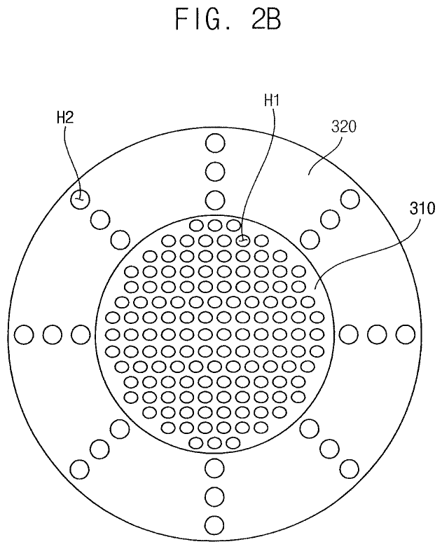

FIG. 1 is a perspective view illustrating a shower head for a substrate treating apparatus in accordance with an example embodiment. FIG. 2A is a cross-sectional view of the shower head cut along a line I-I′ of FIG. 1 and FIG. 2B is a rear view of the shower head shown in FIG. 1.

Referring to FIGS. 1, 2A, and 2B, a shower head 300 in accordance with an example embodiment may include a central head 310 having a plurality of central holes H1 (through which a first injection gas IG1 may be supplied over a central portion of a substrate) and a peripheral head 320 enclosing the central head 310 and having a plurality of peripheral holes 142 (through which a second injection gas IG2 may be supplied over a peripheral portion of the substrate). In an implementation, an overall or total hole area of the peripheral holes H2 (e.g., a sum of areas of all of the peripheral holes H2) may be smaller than a total hole area of the central holes H1 (e.g., a sum of areas of all of the central holes H1). In an implementation, the shower head 300 may be exemplarily provided for a deposition apparatus.

In an implementation, the shower head 300 may be shaped into a disk having an inner space therein and may include the central head 310 at a central portion of the disk and the peripheral head 320 enclosing or surrounding the central head 310.

The central head 310 may have a closed cylinder shape having a first injection space IS1 defined by the cylinder. The peripheral head 320 may have a reverse (e.g., inverted) cup shape enclosing the central head 310 and having a second injection space IS2, separate from the first injection space IS1, and defined by the cylinder and the cup. The peripheral head 320 may have a greater diameter and height than the central head 310, and an inner space of the cup-shaped peripheral head 320 (defined by the central head 310 and the reverse cup) may be a ring-shaped space. The ring-shaped space may include the second injection space IS2 at a lower portion and a flow path P at an upper portion. The second injection space IS2 may have the same height as the first injection space IS1 and the flow path P may be arranged above the first and second injection spaces IS1 and IS2.

A transfer line T may extend into the peripheral head 320 and the central head 310 and the source gases for forming a deposition layer on the substrate may be supplied into the first and the second injection spaces IS1 and IS2 through the transfer line T from an exterior source tank. In an implementation, the transfer line T may have a composite tube shape in which a pair of tubes may be arranged at a common central axis (e.g., may be concentric tubes having different radii). In an implementation, the transfer line T may include a first tube T1 and a second tube T2. The first tube T1 may be inside the second tube T2 and may be connected or in fluid communication with the first injection space IS1 penetrating into the central head 310. The second tube T2 may enclose the first tube T1 and may penetrate into the peripheral head 320. In an implementation, the second tube T2 may be connected to the flow path P and the source gases may be supplied into the second injection space IS2 via the flow path P.

The first and second tubes T1 and T2 may be separated from each other without interconnection with each other and may be connected to the same source tank containing the source gases. In an implementation, the source gases may be individually supplied into the central head 310 and the peripheral head 320 from the same source tank. In an implementation, the source gases flowing into the first tube T1 from the source tank may be supplied into the first injection space IS1 as first source gases S1 and the source gases flowing into the second tube T2 from the source tank may be supplied into the second injection space IS2 via the flow path P as second source gases S2.

The first source gases S1 may be uniformly injected over the central portion of the substrate through the central holes H1 as the first injection gas IG1 (e.g., the first injection gas IG1 may have the same composition as the first source gases S1) and the second source gases S2 may be uniformly injected over the peripheral portion of the substrate through the peripheral holes H2 as the second injection gas IG2 (e.g., the second injection gas IG2 may have the same composition as the second source gases S2).

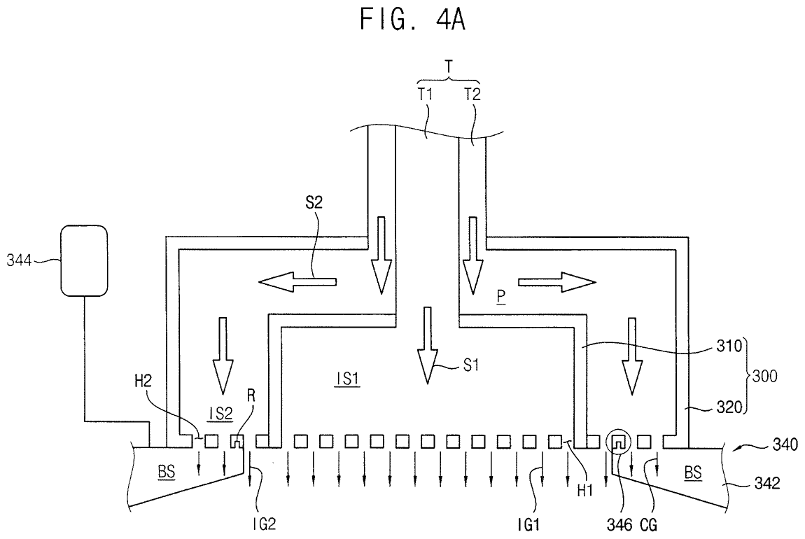

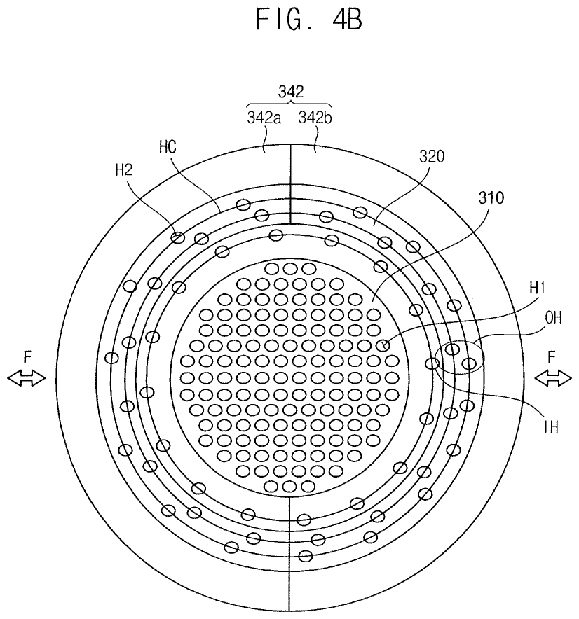

In an implementation, the central hole H1 may have a first size (e.g., area) and a plurality of the central holes H1 may be uniformly and densely arranged on (e.g., a rear surface of) the central head 310 just like a hole compilation or array. In an implementation, the peripheral hole H2 may have a second size (e.g., area) that is larger than the first size, and a plurality of the peripheral holes H2 may be uniformly and sparsely or less densely arranged on (e.g., a rear surface of) the peripheral head 320. In an implementation, a series (e.g., some) of the peripheral holes H2 may be arranged along a single circumferential line enclosing the central head 310 and at a same interval. In an implementation, the central head 310 and the peripheral head 320 may have a common center, and a series of the peripheral holes H2 along the circumferential line may be provided as a circular hole chain enclosing the central head 310. A number of the hole chains HC (see, e.g., FIG. 4B) may be outwardly arranged (e.g., at a same interval) in a radial direction of the peripheral head 320. In an implementation, three hole chains may be provided around the central head 310. In an implementation, 3 or more hole chains may be arranged on the rear surface of the peripheral head 320 according to the configurations and requirements of the substrate treating apparatus including the shower head.

In an implementation, the hole area and the number of the peripheral holes H2 may be controlled or selected in such a way that the total hole area of the peripheral holes H2 may be sufficiently smaller than the total hole area of the central holes H1.

In an implementation, although the same amount of the first and second source gases S1 and S2 may flow into the first and the second tubes T1 and T2 from a single source tank, the flux of the second injection gas IG2 (e.g., an amount of the second injection gas IG2 provided to the substrate) may be smaller than that of the first injection gas IG1.

In some deposition apparatuses, various pattern structures may be arranged on the central portion of the substrate and few pattern structures may be arranged on the peripheral portion of the substrate, and a deposition surface may be much larger at the central portion than at the peripheral portion. If the first injection gas IG1 and the second injection gas IG2 were to be be injected into a process chamber at the same flux, the deposition layer on the central portion of the substrate may be formed on a larger deposition surface to a relatively smaller thickness and the deposition layer on the peripheral portion of the substrate may be formed on a smaller deposition surface to a relatively larger thickness. When a planarization process is then conducted to the deposition layer on the substrate, the removed particles of the deposition layer on the peripheral portion may be provided into an edge portion between the peripheral portion and a side surface of the substrate and a bevel portion of the substrate, to thereby form a residual layer on the edge portion and the bevel portion of the substrate. The residual layer could functions as a particle source in a subsequent process to the pattern structures at the central portion of the substrate.

According to an example embodiment, in the shower head 300, the flux of the second injection gas IG2 may be controlled to be smaller than that of the first injection gas IG1 by controlling the total hole area ratio in such a configuration that the thickness of the deposition layer on the peripheral portion of the substrate may be sufficiently close to the thickness of the deposition layer on the central portion of the substrate. Accordingly, the deposition layer may be uniformly formed on the substrate across the central portion and the peripheral portion, so that the number or volume of particles separated from the deposition layer on the peripheral portion of the substrate in the planarization process may be sufficiently reduced, to thereby help prevent the formation of the residual layer on the edge portion and the bevel portion of the substrate.

In an implementation, when forming a metal layer on the substrate, the total hole area of the peripheral holes H2 may be in a range of about 40% to about 60% of the total hole area of the central holes H1. Maintaining the total hole area of the peripheral holes H2 at about 40% or greater of the total hole area of the central holes H1 may help ensure that the deposition layer has a sufficient thickness on the peripheral portion, thereby helping to reduce or prevent various deposition defects from occurring on the peripheral portion of the substrate. Maintaining the total hole area of the peripheral holes H2 at about 60% or less of the total hole area of the central holes H1 may help ensure that the particles are sufficiently reduced at the edge area of the substrate in a subsequent planarization process. In an implementation, the total hole area of the peripheral holes H2 may be in a range of about 40% to about 60% of the total hole area of the central holes H1. In an implementation, the total hole area ratio of the peripheral holes H2 with respect to the total hole area of the central holes H1 may be varied according to a size of the substrate and the characteristics of the pattern structure on the central portion of the substrate.

In an implementation, the size the peripheral holes H2 may be greater than that of the central holes H1. In an implementation, the peripheral holes H2 and the central holes H1 may have the same size. In an implementation, the number of the peripheral holes H2 may be sufficiently smaller than that of the central holes H1 in such a way that the total hole area of the peripheral holes H2 may be in a range of about 40% to about 60% of the total hole area of the central holes H1.

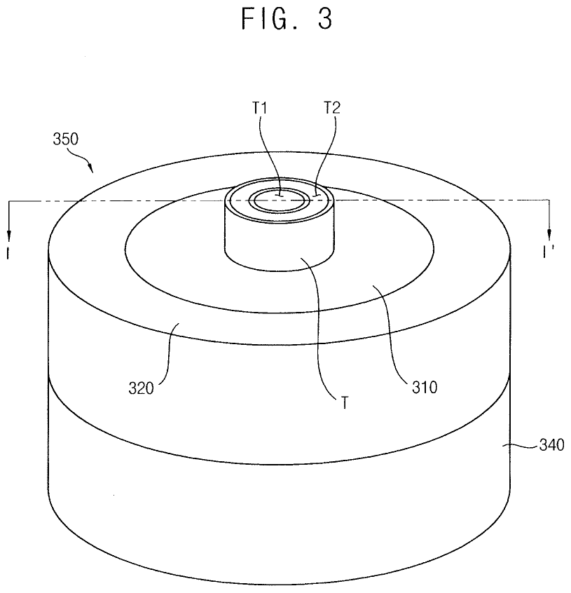

FIG. 3 is a perspective view illustrating a shower head for a substrate treating apparatus in accordance with another example embodiment. FIG. 4A is a cross-sectional view of the shower head cut along a line II-II′ of FIG. 3 and FIG. 4B is a rear view of the shower head shown in FIG. 3.

In FIGS. 3, 4A, and 4B, a shower head 350 in accordance with another example embodiment may have substantially the same structures as the shower head 300 shown in FIGS. 1, 2A and 2B, except that a flow cover 340 may be further provided at a bottom of the shower head 350 and the peripheral holes H2 and the central holes H1 may have the same size. Thus, in FIGS. 3, 4A and 4B, the same reference numerals denote the same elements in FIGS. 1, 2A and 2B, and repeated detailed descriptions on the same elements may be omitted.

Referring to FIGS. 3, 4A and 4B, the shower head 350 in accordance with another example embodiment may include the central head 310 having a plurality of the central holes H1, a peripheral head 320 enclosing the central head 310 and having a plurality of peripheral holes H2, and a flow cover 340 detachably combined to or coupled with the peripheral head 320 and controlling the flow of the second injection gas IG2.

In an implementation, the central head 310 may have a closed cylinder shape and the peripheral head 320 may have a reverse cup shape enclosing the central head 310. In an implementation, the flow cover 340 may have a ring shape arranged such that the central head 310 may be exposed through the (e.g., open center of the) flow cover 340 and the peripheral head 320 may be partially covered by the flow cover 340.

In an implementation, the flow cover 340 may include a ring body 342 in contact with (e.g., a rear surface of) the peripheral head 320 in an arrangement such that some of the peripheral holes H2 may be covered with the ring body 342 and the rest or remaining ones of the peripheral holes H2 may be exposed through the ring body 342. In an implementation, the flow cover 340 may include a cover driver 344 to drive the ring body 342, e.g., to move toward or away from the peripheral head 320, and a coupler 346 coupling the ring body 342 to the peripheral head 320.

The ring body 342 may include a pair of body pieces 342a and 342b that may be arranged under or on the peripheral head 320 and be individually operated. In an implementation, the ring body 342 may have a circular ring shape, and a pair of the body pieces 342a and 342b may each be a half ring corresponding to a half of the ring body 342. The shape and number of the body pieces 342a and 342b may be varied according to the configurations of the shower head 300 and the operation characteristics of the ring body 342.

In an implementation, a plurality of the peripheral holes H2 may be provided in the peripheral head 320 in such a configuration that a number of the hole chains HC may be arranged in the same gap distance in a radial direction of the peripheral head 320, and an inner profile of the ring body 342 may have a circumferential line between neighboring hole chains. In such a case, a center of the peripheral head 320 may be provided as a common center of the ring body 342 and the hole chain.

In an implementation, the flow cover 340 may be installed on (e.g., the rear surface of) the peripheral head 320, and the body pieces 342a and 342b may move linearly to an area under the peripheral head 320 from an opposite side portions of the peripheral head 320 and then may be combined into the flow cover 340 by the cover driver 344. In an implementation, the flow cover 340 may be removed from the peripheral head 320, and the flow cover 340 may be separated into the body pieces 342a and 342b at first and then may move linearly to the opposite side portions of the peripheral head 320 by the cover driver 344. In an implementation, the cover driver 344 may be positioned at a sidewall of the process chamber. In an implementation, the cover driver 344 may be positioned at an exterior of the process chamber.

When the flux of the second injection gas IG2 is to be reduced, the cover driver 344 may drive the ring body 342 to move a coupling position under the rear surface of the peripheral head 320. In an implementation, the amount of the second injection gas IG2 may be reduced, and the amount of the first injection gas IG1 may be unchanged. In an implementation, the ring body 342 may be positioned under the peripheral head 320 in such a configuration that some of hole chains HC close to the central head 310 may be exposed through the ring body 342 and remaining ones of the hole chains HC may be covered with the ring body 342 (e.g., blocking the gas from flowing therethrough).

The coupler 346 may be positioned at the ring body 342 and facing the peripheral head 320 and may couple the ring body 342 with the peripheral head 320. The ring body 342 could move under the peripheral head 320 when the second injection gas IG2 is being injected. In an implementation, the coupler 346 may couple the ring body 342 to the peripheral head 320 (e.g., to fix the ring body 342 in place) in spite of the injection pressure of the second injection gas IG2.

In an implementation, the coupler 346 may include a protrusion extending upwardly from the ring body 342. A (e.g., complementary) recess R (e.g., for holding or accommodating the protrusion) may be arranged at a gap area between the neighboring hole chains HC. In an implementation, the protrusion may be inserted into the recess R, and the ring body 342 may be secured to the peripheral head 320.

In an implementation, the recess R may be provided as a recess trench continuously extending along a circumferential line in the gap area. In an implementation, the recess R may be provided as a plurality of grooves spaced apart at the same gap along the circumferential line in the gap area.

In an implementation, the ring body 342 may be coupled to the peripheral head 320 in the gap area, an inner hole chain IH (of which the circumferential line is smaller than the circumferential line of an inner circle of the ring body 342, e.g., a hole chain HC having a radius smaller than the radius of the inner side of the ring body 342) may be exposed toward the substrate, and an outer hole chain OH (of which the circumferential line is greater than the circumferential line of an inner circle of the ring body 342, e.g., a hole chain HC having a radius greater than the radius of the inner side of the ring body 342) may be covered by the ring body 342. In an implementation, the second source gases S2 may be supplied onto the peripheral portion of the substrate only through the peripheral holes H2 of the inner hole chain IH, and the peripheral holes H2 of the outer hole chain OH may be blocked by the ring body 342.

In an implementation, a buffer space BS may be provided in the ring body 342 and some of the peripheral holes H2 of the outer chain hole HC may be connected to or in fluid communication with the buffer space BS. In an implementation, the outer hole chain OH may be blocked by the ring body 342, and the second injection gas IS2 may flow into the buffer space BS and then may be collected into a collection box. In an implementation, the collected gas may be transferred back to the second tube T2 and may be recycled in the substrate treating process.

In an implementation, the amount of the second injection gas IG2 (e.g., provided to the substrate) may be easily reduced just by changing the coupling position of the ring body 342 to the peripheral head 320. In an implementation, the ring body 342 may be coupled to the peripheral head 320 in such a configuration that only an outermost hole chain HC may be blocked by the ring body 342, the remaining (e.g., two) hole chains HC may be exposed through the ring body 342, and a larger amount of the second injection gas IG2 may be injected over the peripheral portion of the substrate. In an implementation, although the central holes H1 and the peripheral holes H2 may have the same hole size and the first and second source gases S1 and S2 may have the same flux, the amount of the second injection gas IG2 (e.g., provided to a peripheral region of the substrate) may be sufficiently reduced just by blocking some of the peripheral holes H2 by the flow cover 340.

In an implementation, three hole chains may be arranged on the peripheral head 320, the innermost hole chain may be exposed through the flow cover 340, and the remaining two hole chains may be blocked by the flow cover 340. In an implementation, the blocked hole chain may be changed according to the required amount of the second injection gas IG2.

In an implementation, the amount of the second injection gas IG2 may be controlled by changing the hole size or the hole number of the peripheral holes H2 of the peripheral head 320. In an implementation, the amount of the second injection gas IG2 may be controlled by changing the coupling position of the ring body 342 with the peripheral head 320.

In an implementation, the thickness of the deposition layer on the peripheral portion of the substrate may be controlled to be within an allowable range, and the production of particles may be sufficiently prevented in the edge portion of the substrate in a subsequent planarization process.

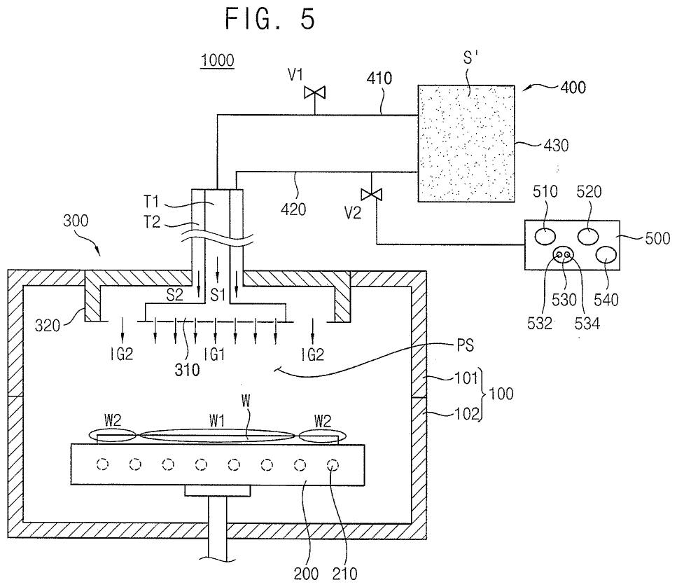

FIG. 5 is a structural view illustrating a substrate treating apparatus including a shower head shown in FIGS. 1 to 2B. In an implementation, as illustrated in FIG. 5, the substrate treating apparatus may be a plasma deposition apparatus. In an implementation, the substrate treating apparatus may include a suitable substrate treating apparatus that forms a thin layer on the substrate by using source gases.

Referring to FIG. 5, a substrate treating apparatus 1000 in accordance with an example embodiment may include a process chamber 100 (in which a substrate treating process may be performed on a substrate W to form a deposition layer on the substrate W), a substrate holder 200 (arranged at a lower portion of the process chamber and on which the substrate W may be secured), a shower head 300 (arranged at an upper portion of the process chamber and including a central head 310 from which a first injection gas may be injected over a central portion of the substrate W and peripheral head 320 from which a second injection gas may be injected over a peripheral portion of the substrate W), a gas supplier 400 (to supply source gases to the shower head 300 and including a first source line 410 connected to the central head 310 and a second source line 420 connected to the peripheral head 320), and a flow controller 500 (to control the shower head 300 and the gas supplier 400 such that a flux of the second injection gas IG2 may be controlled to uniformize a thickness of the deposition layer across the central portion W1 and the peripheral portion W2 of the substrate W.

In an implementation, the flow controller 500 may control a flux of the second injection gas IG2 in such a way that a thickness of the deposition layer is uniform across the central portion W1 and the peripheral portion W2 of the substrate W.

In an implementation, the process chamber 100 may include an upper housing 101 in which the shower head 300 may be installed and a lower housing 102 in which the substrate holder 200 may be installed.

The upper housing 101 may be detachably combined with the lower housing 102 in such a configuration that an inner space of the lower housing 102 may be isolated from surroundings. In an implementation, the inner space of the lower housing 102 may be sealed from surroundings by the upper housing 101 and may be provided as a plasma space PS for conducting the plasma process to the substrate W. In an implementation, the plasma space PS may be provided between the substrate W and the shower head 300 in the process chamber 100. The upper housing 101 and the lower housing 102 may have a sufficient strength and rigidity for the plasma process in the plasma space PS, so that the plasma process may be performed on the substrate W in the process chamber 100 with high reliability and stability.

In an implementation, the substrate holder 200 may be arranged at a central portion of the bottom of the lower housing 102 and the substrate W may be secured onto the substrate holder 200. The substrate holder 200 may include a body secured to the bottom portion of the lower housing 102, a holding member combined at an upper portion of the body and to which the substrate W may be secured, and a lower electrode 210 to which a high frequency power may be applied.

The body may include a conductive material such as aluminum (Al) and may have a sufficient size and configurations for accommodating the holding member. The lower electrode may be provided under the holding member in the body and the high frequency power may be applied to the lower electrode 20 for applying a bias power to the plasma in the plasma space PS. An upper electrode may also be provided with the process chamber 100 and another high frequency power may be applied to the upper electrode to generate an electric field in the plasma space PS. The source gases may be changed into a plasma state due to the energy of the electric field in the plasma space PS and the plasma in the plasma space PS may be forced to move toward the substrate W by the bias power.

In an implementation, the holding member of the substrate holder 200 may include an electrostatic chuck (ESC) having a pair of polyimide films and a conductive layer between the pair of polyimide films. In an implementation, other suitable holders may also be utilized as the holding member as long as the substrate W may be sufficiently secured to the substrate holder 200. In an implementation, the holding member may include a mechanical holder such as a clamp.

The shower head 300 may be positioned at an upper portion of the process chamber 100 and the source gases may be supplied into the process chamber 100 through the upper housing 101.

The source gases S may be supplied into the plasma space PS through the central head 310 and the peripheral head 320 and may be changed into plasma in the process chamber.

The source gases S may be individually supplied into the central head 310 and the peripheral head 320 of the shower head 300 through a first tube T1 and a second tube T2, respectively. The gas supplier 400 may include the first source line 410 connected to the first tube T1 and the second source line 420 connected to the second tube T2. First source gases S1 may flow into the first source line 410 and may be supplied into the central head 310 via the first tube T1 and second source gases S2 may flow into the second source line 420 and may be supplied into the peripheral head 320 via the second tube T1. The first source gases S1 and the second source gases S2 may be individually supplied into the central head 310 and the peripheral head 320 from a source tank 430 that may be positioned at an exterior of the process chamber 100.

The first source gases S1 may be supplied into the plasma space over the central portion W2 of the substrate W as the first injection gas IG1, and the second source gases S2 may be supplied into the plasma space over the peripheral portion W2 of the substrate W as the second injection gas IG2.

In an implementation, the amount of the second injection gas IG2 may be controlled by changing the hole size and the hole number of the peripheral holes H2 of the peripheral head 320.

In an implementation, the amount of the second injection gas IG2 (e.g., provided to the plasma space PS) may be smaller than that of the first injection gas IG1, and the plasma density may be smaller over the peripheral portion W2 of the substrate W than over the central portion WI of the substrate W. In an implementation, the thickness of the deposition layer on the peripheral portion W2 may be controlled within a desired range that is close to the thickness of the deposition layer on the central portion W1, and thus the particles separated from the deposition layer on the peripheral portion W2 may be sufficiently reduced in a subsequent planarization process.

The configurations and structures of the shower head 300 may be the same as those of the shower head 300 described in detail with reference to FIGS. 1 to 2B. Thus, any further repeated detailed descriptions on the shower head 300 may be omitted.

In an implementation, the shower head 300 of the substrate treating apparatus shown in FIG. 5 may include the shower head 350 shown in FIGS. 3, 4A, and 4B.

In such a case, a plurality of the peripheral holes 112 may be arranged into the circular hole chains HC enclosing the central head 310 at different diameters, and the ring-shaped flow cover 340 may be positioned in the gap area between the neighboring hole chains HC. In an implementation, the inner hole chain IH may be exposed toward the plasma space PS though the flow cover 340 and the outer hole chain OH may be blocked by the flow cover 340.

In an implementation, the second injection gas IG2 may be supplied into the plasma space PS only through the inner hole chain(s) IH and may not be supplied into the plasma space PS though the outer hole chain(s) OH.

In an implementation, the amount of the second injection gas IG2 may be controlled or reduced by changing the coupling position of the flow cover 340 to the peripheral head 320. In an implementation, the amount of the second injection gas IG2 (e.g., supplied to the plasma space PS) may be about 40% to about 60% of the amount of the first injection gas IG1. The configurations and structures of the shower head 300 may be the same as those of the shower head 350 described in detail with reference to FIGS. 3 to 4B. Thus, any further repeated detailed descriptions on the shower head 300 may be omitted.

The source gases S′ may be contained in the source tank 430 and may individually flow into the first source line 410 as the firs source gases S1 and the second source line 420 as the second source gases S2. The first source gases S1 and the second source gases S2 may have substantially the same compositions as the source gases S′ in the source tank 430. When a metal layer is to be formed on the substrate W by a deposition process, the source gases may include, e.g., a metal source, a deoxidizing gas, and a purge gas.

In an implementation, when a tungsten layer is to be formed on the substrate W, the metal source may include, e.g., tungsten fluoride (WF₆), and the deoxidizing gas may include, e.g., hydrogen gas (H₂). An inactive or inert gas, e.g., an argon (Ar), gas may be used as the purge gas.

A first control valve V1 may be on the first source line S1 to control the amount of the first source gases S1 and a second flow control valve V2 may be on the second source line S2 to control the amount of the second source gases S1. The first control valve V1 and the second control valve V2 may be connected to the flow controller 500, so that the amounts of the first and the second source gases S1 and S2 may be controlled by the flow controller 500.

In an implementation, the flow controller 500 may control the first injection gas IG1 and the second injection gas IG2 in such a way that the deposition layer may be formed on the central portion W1 of the substrate W to a desired thickness, and minimizing the particles separated from the deposition layer in a planarization process on the peripheral portion W2 may be sufficiently reduced.

The flow controller 500 may include a first controller 510 for controlling the substrate treating process to the substrate W in the process chamber 100, a second controller 520 for controlling the cover driver 344 to move the ring body 342 to the coupling position of the peripheral head 320, a layer detector 530 detecting layer information of the deposition layer on the central portion W1 and the peripheral portion W2 of the substrate W, respectively, and a central processor 540 for controlling the first controller 510, the second controller 520, and the layer detector 530 in such a way that the deposition layer may be formed to a desired thickness at both of the central portion W1 and the peripheral portion W2 of the substrate W with minimizing the particles in the edge portion of the substrate W.

In an implementation, the first controller 510 may control the substrate treating process to the substrate W in the process chamber 100. When a metal layer is to be formed on the substrate W by a deposition process, a deposition source including the metal, a de-oxidizing gas, and a purge gas may controlled by the first controller 510 I in such a way that the deposition source, the de-oxidizing gas, and the purge gas may be supplied to the shower head 300 at an appropriate amount in an appropriate step and thus the deposition layer may be formed on the central portion W1 of the substrate W to the desired thickness.

In an implementation, the the shower head 300 may be configured into the shower head 300 shown in FIGS. 1 to 2B, and the amount of the second injection gas IG2 may be smaller than the that of the first injection gas IG1 according to the ratio of the total hole areas of the central holes H1 and the penetration holes H2. In an implementation, the source gases may be supplied into the plasma space PS at the peripheral portion W2 of the substrate W in an amount less than that at the central portion W1 of the substrate W.

In an implementation, the deposition layer on the peripheral portion W2 of the substrate W may have a thickness almost equal to a thickness of the deposition layer on the central portion W1 of the substrates W. In an implementation, the presence of particles separated from the deposition layer on the peripheral portion W2 may be sufficiently reduced in a subsequent planarization process, e.g., due to the thickness uniformity of the deposition layer on a whole substrate W.

In an implementation, the shower head 300 may be configured into the shower head 350 shown in FIGS. 3 to 4B, and the flow cover 340 may be selectively coupled to the rear surface of the peripheral head 320 in such a way that the second injection gas IG2 may be smaller than the first injection gas IG1 and the thickness of the deposition layer may become uniform on a whole substrate W.

In an implementation, the flow cover 340 may be coupled to the peripheral head 320 at an appropriate coupling position, and the inner hole chain IH may be exposed through the ring-shaped flow cover 340 and the outer hole chain OH may be blocked by the flow cover 340. In an implementation, the second injection gas IG2 may be injected into the plasma space PS only though the penetration holes H2 of the inner hole chain IH and may not be injected though the penetration holes H2 of the outer hole chain OH.

The layer detector 530 may detect the layer information of the deposition layer at the peripheral portion W2 as well as the central portion W1 of the substrate W periodically or in a real time together with the first and the second source gases S1 and S2. The layer information may include a deposition conditions, a layer composition, and a layer thickness.

In an implementation, if the thickness of the depositor layer on the central portion W1 were to deviate from an expected or desired thickness, the thickness information may be transferred to the first controller 510. Then, the amount of the deposition source and the de-oxidizing gas may be controlled by the first controller 510 and the amount of the first injection gas IG1 may be changed in such a way that the thickness of the deposition layer may be formed on the central portion W2 to the expected thickness.

The layer detector 530 may include a particle database 532 and a position determinant 534 for determining the coupling position of the flow cover 340. In an implementation, the layer detector 530 may detect the process defects caused by the particles from the deposition layer on the peripheral portion W2 of various substrates and may generate correlations between the particles and the amount of the second injection gas IG2 and between the particles and the conditions of the substrate treating process. Then, the correlation of the particles with respect to the second injection gas IG2 and the process conditions may be stored in the particle database 532.

In an implementation, the substrate treating process may be initiated in the process chamber 100, and the position determinant 534 may determine an initial coupling position of the flow cover 340 based on the particle database 532 and the amount of the second source gases S2. The initial coupling position may be transferred to the second controller 520, and then the second controller 520 may operate the cover driver 344 to move the ring body 342 to the initial coupling position under the peripheral head 320.

In an implementation, the flow cover 340 may be located at the initial coupling position when initiating the substrate treating process in the process chamber 100, and the amount of the second injection gas IG2 may be reduced and the deposition layer may be formed on the substrate W to a substantially uniform thickness across the peripheral portion W2 and the central portion W1.

In an implementation, the gas supplier 400 may be configured in such a configuration that the same amount of the first source gases S1 and the second source gases S2 may flow through the first source line 410 and the second source line 420, and the amount change of the first source gases S1 may necessarily cause the amount change of the second source gases S2.

In an implementation, the first controller 510 may increase the amount of the first source gases S1 for removing the thickness deviation, the second source gases S2 may also increase as much as the first source gases S1, and as a result, the second injection gas IG2 may inevitably increase.

In such a case, the amount increase of the source gas S2 may be transferred to the position determinant 534 by the central processor 540 and the position determinant 534 may also determine a modified coupling position based on the amount increase of the source gas S2. Then, the flow cover 340 may move to the modified coupling position from the initial coupling position in such a way that the amount increase of the second source gases S2 may be counterbalanced by the flow cover 340, and the initial or desired amount of the second injection gas IG2 may be maintained in spite of the increase of the second source gases S2 (e.g., provided to the shower head 300).

In an implementation, the first controller 510 may decrease the amount of the first source gases Si for removing the thickness deviation, the second source gases S2 may also decrease as much as the first source gases S1, and as a result, the second injection gas IG2 may inevitably decrease. In such a case, the layer detector 530 may also determine another modified coupling position to which the flow cover 340 may move from the initial coupling position in such a way that the amount decrease of the second source gases S2 may be counterbalanced by the flow cover 340, and the initial or desired amount of the second injection gas IG2 may be maintained, in spite of the decrease of the second source gases S2. In an implementation, a larger number of the hole chains may be exposed through the flow cover 340 at another coupling position. In an implementation, the flow cover 340 may be removed from the peripheral head 320.

Then, the modified coupling position may be transferred to the second controller 520 and the second controller 520 may operate the cover driver 344 to move the ring body 342 to the modified coupling position from the initial coupling position.

In an implementation, the layer detector 530 may detect the process defects caused by the particles from the deposition layer on the peripheral portion W2 whenever the process conditions are changed at the peripheral head 320. In an implementation, the particle database may be updated whenever the second injection gas IG2 is changed. In an implementation, the correlation of the particles with respect to the second injection gas IG2 and the process conditions may be updated in the particle database.

The central processor 540 may control the first controller 510, the second controller 520, and the layer detector 530 in such a way that the deposition layer may be formed on the central portion W2 of the substrate W to an expected or desired thickness while minimizing particles in the edge portion of the substrate W (e.g., during a subsequent process).

In an implementation, the substrate treating process may be initiated in the process chamber 100, and the central processor 540 may control the first controller 510 to flow the first and the second source gases S1 and S2 at an initial amount and may transfer the initial amounts of the first and the second source gases S1 and S2 and the process conditions to the position determinant 534 of the layer detector 530. Then, the position determinant 534 may determine the initial coupling position based on the transferred amount of the second source gases S2 and the particle database.

In an implementation, when the amount of the first source gases S1 is changed by the first controller 510, the amount change of the second source gases S2 may also be detected from the central processor 540 and may be transferred to the position determinant 533 for determining the modified coupling position.

A plurality of conductive structures and an insulation pattern structure may be intensively arranged on the central portion W2 of the substrate W. In an implementation, the conductive structure may include a transistor of a memory device such as a DRAM device and a MRAM device and a contact structure connected to a drain electrode of the transistor. In an implementation, the metal layer deposited on the central portion W2 of the substrate W may be a lower electrode of a data storage unit of the MRAM.

By way of summation and review, a pattern structure may be intensively formed on the central portion of a substrate, and the deposition surface of the central portion may be much larger than that of the peripheral substrate. The deposition layer may have a greater thickness on the peripheral portion than on the central portion of the substrate.

When a subsequent planarization process is conducted on the deposition layer, the deposition layer on the peripheral portion may be firstly planarized and the particles generated from the deposition layer on the peripheral portion of the substrate may be intensively stacked on an edge portion and a bevel portion of the substrate, to thereby generate a residual layer on the edge portion and the bevel portion of the substrate. A plurality of particles may be generated from the residual layer when a subsequent process is conducted on the pattern structures, to generate various process defects in a deposition process.

In some shower heads for a substrate treating apparatus, the same amount of first source gases and second source gases may be supplied, and the deposition layer on the peripheral portion W2 may have a thickness greater than the deposition layer on the central portion W1 because the central portion W1 of the substrate W has a larger deposition surface than the peripheral portion W2 of the substrate W due to the conductive structure and the insulation pattern structures.

According to an example embodiment of the shower head, the second injection gas IG2 may be selectively blocked or opened in such a way that the amount of the second injection gas IG2 injected from the peripheral head 320 may be smaller than that of the first injection gas IG1 injected from the central head 310. Thus, the thickness of the deposition layer on the peripheral portion W2 of the substrate W may be close to the thickness of the deposition layer on the central portion W1 of the substrate W. Accordingly, the particles generated from the deposition layer in a subsequent planarization process on the peripheral portion W2 of the substrate W may be sufficiently reduced.

According to the example embodiments, the second injection gas injected from the peripheral head may be controlled in such a way that the amount of the second injection gas may be smaller than that of the first injection gas injected from the central head just by changing the hole size and the hole number of the peripheral holes of the peripheral head or just by changing the coupling position of a flow cover with the peripheral head.

Thus, the thickness of the deposition layer on the peripheral portion of the substrate may be considerably close to the thickness of the deposition layer on the central portion of the substrate, in spite of the density of pattern structures on the central portion of the substrate, so that the thickness of the depositor layer may be substantially uniform along a whole surface of the substrate. The deposition layer may have a uniform thickness in the central portion and the peripheral portion, and particles separated from the deposition layer on the peripheral portion in a subsequent planarization process may be sufficiently reduced or prevented. Accordingly, process defects caused by the particles in the edge portion of the substrate may be reduced, and the reliability of the substrate treating process may be improved in the substrate treating apparatus.

One or more embodiments may provide a shower head for a substrate treating apparatus for controlling an amount of the source gases supplying into a process chamber over a peripheral portion of the substrate to help improve a thickness uniformity of a deposition layer on the substrate.

One or more embodiments may provide a shower head including a central head and a peripheral head and a substrate treating apparatus having the same.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A shower head for a substrate treating apparatus, the shower head comprising:
a central head at a central portion of the shower head, the central head having a plurality of central holes through which a first injection gas is injectable; and
a peripheral head at a peripheral portion of the shower head to enclose the central head, the peripheral head having a plurality of peripheral holes through which a second injection gas is injectable,
wherein a total hole area of the peripheral holes is smaller than a total hole area of the central holes.

2. The shower head as claimed in claim 1, wherein the total hole area of the peripheral holes is in a range of 40% to 60% of the total hole area of the central holes.

3. The shower head as claimed in claim 2, wherein:
the plurality of central holes has a first uniform size and is uniformly arranged on the central head,
the plurality of peripheral holes has a second uniform size greater than the first size and is arranged on the peripheral head such that a plurality of hole chains of the peripheral holes surround the central head,
each hole chain includes a series of peripheral holes arranged along a circumferential line enclosing the central head at a same radial distance from the central head, and
the hole chains are radially spaced apart from one another on the peripheral head.

4. The shower head as claimed in claim 2, wherein:
the plurality of the central holes and the plurality of the peripheral holes each have a same size, and
a total number of the plurality of the peripheral holes on the shower head is smaller than a total number of the plurality of the central holes on the shower head.

5. The substrate treating apparatus as claimed in claim 1, wherein:
the central head has a closed cylinder shape having a first injection space therein,
the peripheral head has a reverse cup shape enclosing the central head, the peripheral head having a second injection space in a lower portion thereof and a flow path in an upper portion thereof, and
the second injection space has a same height as the first injection space.

6. A shower head for a substrate treating apparatus, the shower head comprising:
a central head at a central portion of the shower head, the central head having a plurality of central holes through which a first injection gas is injectable;
a peripheral head at a peripheral portion of the shower head to enclose the central head, the peripheral head having a plurality of peripheral holes through which a second injection gas is injectable; and
a flow cover detachably coupled to the peripheral head to control a flow of the second injection gas.

7. The shower head as claimed in claim 6, wherein:
the peripheral head has a reverse cup shape enclosing the central head, and
the flow cover has a ring shape such that the central head is exposed through the flow cover and the peripheral head is partially covered by the flow cover.

8. The shower head as claimed in claim 7, wherein the flow cover includes:
a ring body in contact with the peripheral head such that some of the peripheral holes are covered with the ring body and remaining ones of the peripheral holes are exposed through the ring body,
a cover driver to drive the ring body to move toward or away from the peripheral head, and
a coupler coupling the ring body to the peripheral head.

9. The shower head as claimed in claim 8, wherein:
the plurality of peripheral holes is arranged on the peripheral head such that a series of the peripheral holes are arranged on the peripheral head such that a plurality of hole chains of the peripheral holes surround the central head,
each hole chain includes a series of peripheral holes arranged along a circumferential line enclosing the central head at a same radial distance from the central head,
the hole chains are radially spaced apart from one another on the peripheral head, and
the coupler includes a protrusion protruding from the ring body and is insertable into a recess arranged at a gap area between adjacent hole chains.

10. The shower head as claimed in claim 9, wherein:
the plurality of hole chains includes:
an inner hole chain of which a length of the circumferential line is smaller than a length of a circumferential line of an inner side of the ring body, and
an outer hole chain of which a length of the circumferential line is greater than the length of the circumferential line of the inner side of the ring body, and
the ring body includes a buffer space that is connected to the peripheral holes of the outer hole chain and in which the second injection gas is collectable.

11. A substrate treating apparatus, comprising:
a process chamber in which a substrate treating process to a substrate is conductable to form a deposition layer on the substrate;
a substrate holder at a lower portion of the process chamber and on which the substrate is securable;
a shower head at an upper portion of the process chamber, the shower head including a central head from which a first injection gas is injectable over a central portion of the substrate and peripheral head from which a second injection gas is injectable over a peripheral portion of the substrate such that a flux of the second injection gas is smaller than that of the first injection gas;
a gas supplier to supply the first injection gas and the second injection gas to the shower head, the gas supplier including a first source line connected to the central head and a second source line connected to the peripheral head; and
a flow controller to control the shower head and the gas supplier such that a flux of the second injection gas is controllable to thereby uniformize a thickness of the deposition layer across the central portion and the peripheral portion of the substrate.

12. The substrate treating apparatus as claimed in claim 11, wherein:
the central head is at a central portion of the shower head and includes a plurality of central holes through which the first injection gas is injectable,
the peripheral head is at a peripheral portion of the shower head and includes a plurality of peripheral holes through which the second injection gas is injectable, and
a total hole area of the peripheral holes is smaller than a total hole area of the central holes.

13. The substrate treating apparatus as claimed in claim 12, wherein:
a same amount of the first injection gas and the second injection gas are suppliable to the first source line and the second source line, respectively, and
an amount of the second injection gas injectable over the peripheral portion of the substrate is in a range of 40% to 60% of an amount of the first injection gas injectable over the central portion of the substrate.

14. The substrate treating apparatus as claimed in claim 12, wherein the shower head further includes a flow cover detachably coupled to the peripheral head to control a flow of the second injection gas.

15. The substrate treating apparatus as claimed in claim 14, wherein the flow cover includes:
a ring body in contact with the peripheral head at a coupling position such that some of the peripheral holes are covered with the ring body and remaining ones of the peripheral holes are exposed through the ring body;
a cover driver to drive the ring body to move toward or away from the peripheral head; and
a coupler coupling the ring body to the peripheral head at the coupling position.

16. The substrate treating apparatus as claimed in claim 15, wherein:
the plurality of peripheral holes is arranged on the peripheral head such that a series of the peripheral holes are arranged on the peripheral head such that a plurality of hole chains of the peripheral holes surround the central head,
each hole chain includes a series of peripheral holes arranged along a circumferential line enclosing the central head at a same radial distance from the central head,
the hole chains are radially spaced apart from one another on the peripheral head, and
the coupler includes a protrusion protruding from the ring body and is insertable into a recess arranged at a gap area between adjacent hole chains.

17. The substrate treating apparatus as claimed in claim 16, wherein:
the plurality of hole chains includes:
an inner hole chain of which a length of the circumferential line is smaller than a length of a circumferential line of an inner side of the ring body, and
an outer hole chain of which a length of the circumferential line is greater than the length of the circumferential line of the inner side of the ring body, and
the ring body includes a buffer space that is connected to the peripheral holes of the outer hole chain and in which the second injection gas is collectable.

18. The substrate treating apparatus as claimed in claim 15, wherein the flow controller includes:
a first controller to control the substrate treating process in the process chamber;
a second controller to control the cover driver to move the ring body to a coupling position of the peripheral head;
a layer detector to detect a layer thickness of the deposition layer on the peripheral portion and on the central portion of the substrate, respectively, and to determine the coupling position of the ring body to the peripheral head; and
a central processor to control the first controller, the second controller, and the layer detector such that the deposition layer has an expected thickness at both of the central portion and the peripheral portion of the substrate.

19. The substrate treating apparatus as claimed in claim 18, wherein the layer detector includes a particle database in which correlations between particles separated from the deposition layer on the peripheral portion of the substrate and an amount of the second injection gas and between the particles and process conditions of the substrate treating process are stored and a position determinant for determining the coupling position of the flow cover.

20. The substrate treating apparatus as claimed in claim 18, wherein:
the first injection gas and the second injection gas include tungsten fluoride (WF₆) gas and a de-oxidizing gas, and
the deposition layer includes a tungsten layer for a lower electrode of a data storing unit of a magnetoresistive random access memory (MRAM) device.
